(19) United States
(12) Patent Application Publication
(10) Pub. No.: US 2011/0148128 A1
(43) Pub. Date: Jun. 23, 2011

(54) Semiconductor Wafer Transport System

(75) Inventors: Lance G. Hellwig, Florissant, MO (US); Thomas A. Torack, St. Louis, MO (US); John A. Pitney, St. Peters, MO (US)

(73) Assignee: MEMC ELECTRONIC MATERIALS, INC., St. Peters, MO (US)

(21) Appl. No.: 12/645,565

(22) Filed: Dec. 23, 2009

(51) Int. Cl. H01L 21/677; B25J 15/06

(52) U.S. Cl. 294/64.3

(57) ABSTRACT

A system and a wand are disclosed for the transport of a semiconductor wafer. The system and wand include a plate and a locator. The plate includes a plurality of plate outlets for directing gas flow against the wafer to hold the wafer using the Bernoulli principle. The locator extends from the plate and includes a locating outlet for directing a gas flow to locate the wafer laterally relative to the plate. The plate outlets and the locating outlet operate to prevent the wafer from contacting the plate or the locator. In some embodiments, a plurality of locators are used to locate the wafer laterally relative to the plate.

### BACKGROUND

Semiconductor wafers are often moved during processing operations by a “Bernoulli wand”. The Bernoulli wand utilizes the Bernoulli principle to create a pocket of low pressure directly beneath the wand. The pocket of low pressure is created by an increase in velocity of a flow of gas as it is directed out from the underside of the wand. The low-pressure pocket draws the wafer towards the bottom surface of the wand, while at the same time the flow of gas prevents a top surface of the wafer from contacting the underside of the wand. Downward protruding feet are disposed at the edges of the wand to laterally locate the wafer and prevent the wafer from sliding out from underneath the wand during movement of the wand. The wand feet locate the wafer by contacting edges of the wafer. Because the Bernoulli wands are often used in high-temperature environments, the wand and the feet are made from quartz or other materials resistant to high temperatures. Compliant materials such as plastic are thus not suited for use on the wand feet to reduce or cushion contact between the wafer edge and the wand feet.

### BRIEF SUMMARY

One aspect is a semiconductor wafer transport system comprising a plate and a locator. The plate includes a plurality of plate outlets for directing gas flow against the wafer to hold the wafer using the Bernoulli principle. The locator extends from the plate and includes a locating outlet for directing a gas flow to locate the wafer laterally relative to the plate. The plate outlets and the locating outlet operate to prevent the wafer from contacting the plate or the locator.

Another aspect is a wand for transporting a wafer comprising a plate and a plurality of locators. The plate includes a plurality of plate outlets for directing a gas flow against the wafer to hold the wafer using the Bernoulli principle. The plate has a neck to facilitate positioning the plate. The plurality of locators extends from the plate and each includes a locating outlet for directing a gas flow to locate the wafer laterally relative to the plate. The plate outlets and locating outlets operate to prevent the wafer from contacting the plate or the locator.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a top plan view of an exemplary wand;

FIG. 2 is a partial side view of the exemplary wand of FIG. 1;

FIG. 3 is a top plan view of an exemplary wand foot;

FIG. 4 is a side view of the exemplary wand foot of FIG. 3; and

FIG. 5 is a top plan view of a wand foot of another embodiment.

### DETAILED DESCRIPTION

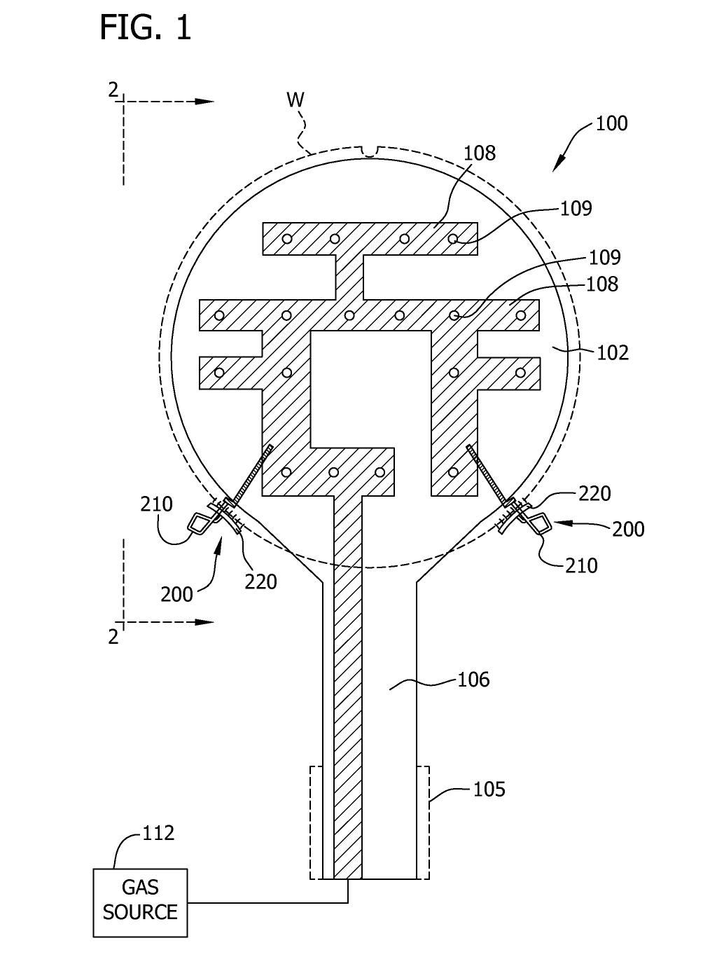

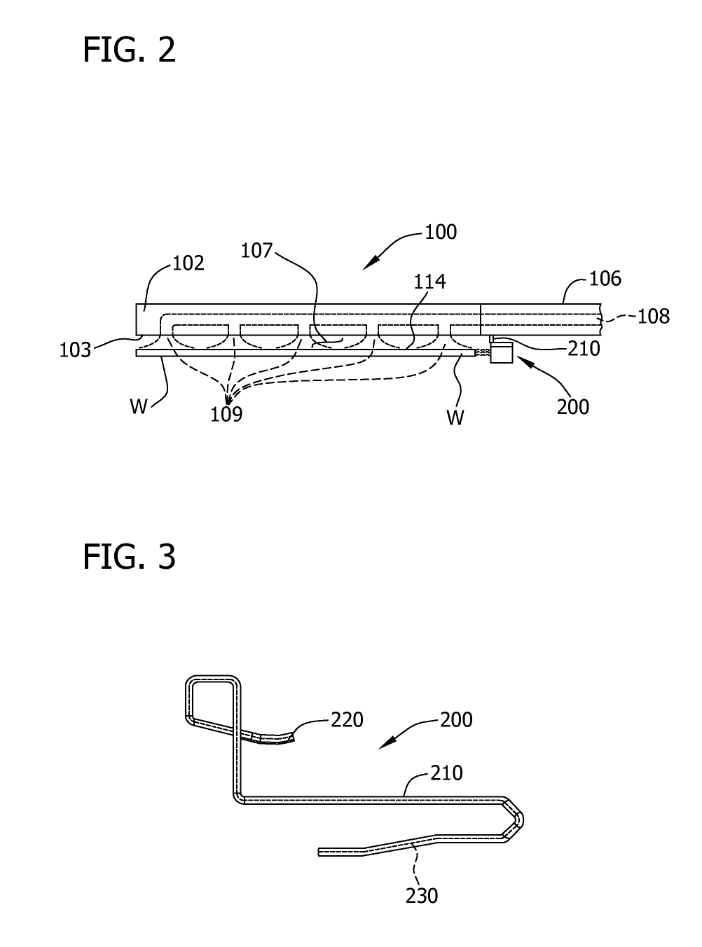

FIGS. 1 and 2 depict an exemplary Bernoulli wand 100 (hereinafter referred to as a “wand”) and a wafer W positioned beneath the wand. In the exemplary embodiment, the wafer W is a semiconductor wafer, while in other embodiments any substrate may be transported by the wand 100. FIG. 1 is a top plan view of the wand 100 while FIG. 2 is a side view of a portion of the wand.

The wand 100 includes a plate 102 having a neck 106 configured for attachment to an arm 105 capable of moving the wand and the wafer W. In some embodiments, the arm 105 is a robotic arm. The wand 100 is formed from any material that is suitably non-reactive at elevated temperatures (e.g., quartz). In other embodiments, the wand 100 does not include the neck 106, and instead the plate 102 is configured for attachment to the arm 105.

The plate 102 of the wand 100 has a plurality of internal passages 108 or channels to direct a flow of gas therethrough. The internal passages 108 direct the flow of gas from a gas source 112 through the neck 106 of the wand 100 and into the interior of the plate 102. The flow of gas exits the wand 100 through a plurality of plate outlets 109 in a bottom surface 103 of the plate 102. The flow of gas exiting the plate 102 is shown in phantom lines in FIG. 2. Each of the plurality of plate outlets 109 are in fluid communication with at least a portion of the internal passages 108. The plurality of plate outlets 109 are circular in shape in the exemplary embodiment, although in different embodiments the plate outlets are differently shaped (e.g., slit-shaped).

In the exemplary embodiment, the plate outlets 109 are configured such that they direct the gas flow at angle as the gas exits the plate 102. In some embodiments, the angle is different for different plate outlets 109 based on their location on the plate 102. The angling of the gas flow through the plate outlets 109 biases the wafer W toward a portion of the wand 100. For example, the wafer W may be biased in the direction of one or more locators (i.e., a pair of wand feet as discussed below). In the exemplary embodiment, the plate outlets 109 are openings formed in the bottom surface 103 of the plate 102. The particular gas directed through the internal passages 108 and out through the plate outlets 109 is any suitable inert gas that will not adversely react with the wafer W (e.g., argon or nitrogen).

As the gas exits the plate outlets 109, a low-pressure zone is formed in an area 107 between the wafer W and the bottom surface 109 of the plate 102 according to the Bernoulli principle. The low-pressure zone is created by the gas as it exits the plate 102 through the plate outlets 109. The low-pressure zone results in the creation of a lifting force that draws the wafer W towards the bottom surface 103 of the plate 102. As a top surface 114 of the wafer W is drawn nearer to the bottom surface 103 of the plate 102, the top surface is prevented from contacting the bottom surface by the flow of gas through the plate outlets 109. While the flow of gas through the plate outlets 109 is sufficient to hold the wafer W in place vertically with respect to the wand 100, the lifting force generated by the flow is not able to laterally position or locate the wafer.

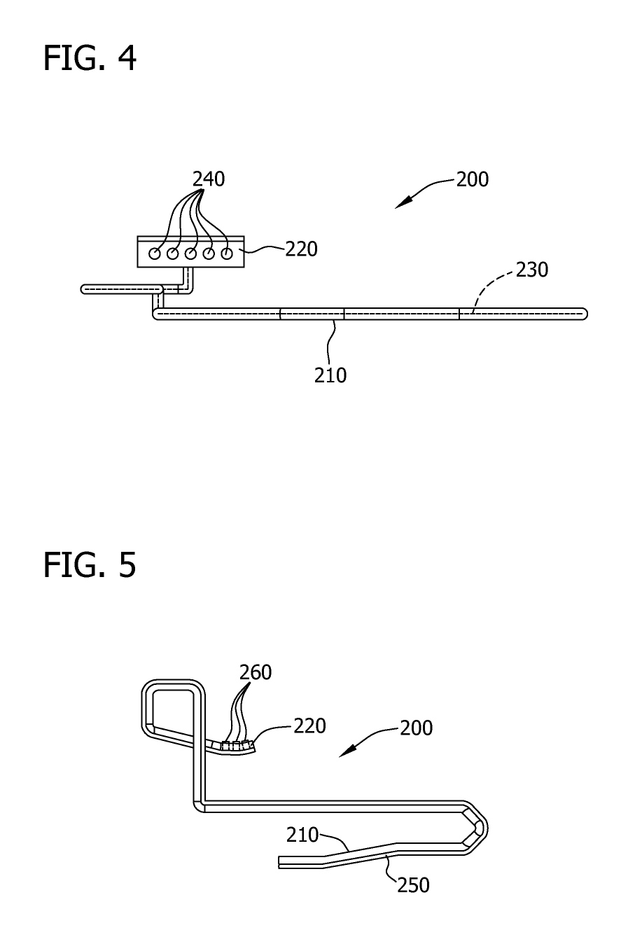

As shown in FIGS. 3 and 4, a pair of feet 200 (broadly “locators”) extend outward from an edge 101 of the wand 100 and downward from the bottom surface 103 of the wand 100. Generally, the feet 200 laterally position the wafer W with respect to the wand 100. While a pair of feet 200 are shown in the exemplary embodiment, any number of feet may be used without departing from the scope of the embodiments. For example, a third foot, in addition to the pair of feet 200, may be used. The third foot may be positioned in between the pair of feet 200 at or near the neck 106 and be configured to prevent rotation of the wafer W. Like the wand 100, the feet 200 are constructed from materials resistant to high temperatures (e.g., quartz).

Each foot 200 has a support structure 210 that attaches a pad 220 to the wand 100. The support structure 210 has an internal passage 230 or channel formed therein for the flow of gas through the structure and out through a locating outlet 240. Like the plate outlets 109, the locating outlets 240 may direct the flow of gas exiting therethrough parallel to the plane defined by the plate 102. The angle at which the gas flow exits through the locating outlets 240 can vary in one embodiment between +/−10 degrees, or in another embodiment between +/−30 degrees relative to the plane. In the exemplary embodiment, there are five locating outlets 240 on the pads 220 of the feet 200, while other embodiments may use more or less outlets without departing form the scope of the embodiments. Moreover, while the locating outlets 240 shown in the Figures are circular-shaped, differently shaped outlets may be used without departing from the scope of the embodiments. For example, in one embodiment the locating outlets 240 are slits formed in the pads 220 that are generally parallel to the plane of the plate 102.

The internal passage 230 of the support structure 210 is in fluid communication with the internal passages 108 of the plate 102 and is supplied by gas from the same gas source 112. Any suitable connector may be used to couple the internal passages 230 of the support structure 210 to those of the plate 102. In other embodiments, the internal passages 230 of the support structure 210 may not be coupled to the internal passages 108 of the plate. Instead, the internal passages 230 may be coupled directly to the gas source 112. While a pair of feet 200 is shown in FIGS. 1 and 2, any number of feet may be used without departing from the scope of the embodiments. In one embodiment, an additional foot is positioned on the plate 102 to engage a notch formed in the edge of the wafer W. The engagement between the additional foot and the notch prevents the wafer W from rotating with respect to the plate 102.

In another embodiment shown in FIG. 5, the gas flow is not directed internally within the support structure 210. Instead, the gas flows through an external conduit 250 disposed adjacent the support structure 210. The conduit 250 is constructed from materials resistant to high temperatures (e.g., quartz). The conduit 250 terminates at or near the pad 220 in a conduit outlet 260 and directs the gas flow in the same direction as in embodiments using the locating outlets 240. In the embodiment of FIG. 5, three conduit outlets 260 are used, although more or less conduit outlets may be used without departing from the scope of the embodiments.

In operation, the wand 100 is used to transport the wafer W during wafer processing operations without physically contacting any part of the wafer, including the edges. In conventional Bernoulli wands, the edges of the wafer contact the wand feet. The contact between the wafer edges and the wand feet damages the edges. The damage caused to the wafer edges may result in the wafer failing to meet quality specifications or render the wafer ill-suited for use in a device.

In one embodiment, the wand 100 transports the wafer W into an epitaxial reactor where the wafer W is subject to an epitaxial growth process in a high-temperature environment that ranges from 1050° C. to 1200° C., while the wand may be subject to temperatures ranging from 600° C. to 950° C. After the growth process is complete, the wafer W is removed from the reactor by the wand 100. During lifting of the wafer W, gas is directed from the gas source 112 through the internal passages 108 of the wand 100 and out through the plate openings 109. At least some of the plate openings 109 are angled relative to the plane defined by the plate 102 such that the flow of gas biases the wafer W in the direction of the feet 200. Gas is also directed through the internal passages 108 of the wand 100 and into the internal passages 230 of the support structure of the feet 200. The gas then flows out from the feet through locator outlets 240. The angled flow of gas through at least some of the plate openings 109 thus biases the wafer W in the direction of the feet 200. The flow of gas through the locator outlets 240 prevents the edge of the wafer W from coming into contact with the pads 220 of the feet.

In some embodiments, multiple pairs of feet 200 are positioned on the edge of the plate 102. In these embodiments, the plate outlets 109 may not be angled as the wafer W does not need to be biased in the direction of any of the feet 200 as the wafer is prevented from moving laterally with respect to the wand 100 by the multiple pairs of feet. In these embodiments, the feet 200 may be positioned at equally spaced locations on the edge of the plate 200 to prevent the lateral movement of the wafer W.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description and shown in the accompanying drawing[s] shall be interpreted as illustrative and not in a limiting sense.

What is claimed is:

1. A semiconductor wafer transport system comprising:
a plate including a plurality of plate outlets for directing gas flow against the wafer to hold the wafer using the Bernoulli principle;
a locator extending from the plate and including a locating outlet for directing a gas flow to locate the wafer laterally relative to the plate;
wherein the plate outlets and locating outlet operate to prevent the wafer from contacting the plate or the locator.

2. The system of claim 1, wherein the plate defines a plane, and the locating outlet directs gas at an angle of between 0 degrees and 10 degrees relative to the plane.

3. The system of claim 1, wherein the locating outlet is a slit extending generally parallel to the plane of the plate

4. The system of claim 1, wherein the locator is a first locator, the system further comprising a second locator spaced from the first locator, the second locator extending from the plate and including a locating outlet for locating the wafer relative to the plate.

5. The system of claim 1, wherein the plate includes a channel disposed therein connecting a gas source to the gas outlets.

6. The system of claim 1, wherein the plate is made of quartz.

7. The system of claim 6, further comprising a neck extending from the plate, and an arm extending from the neck for positioning the plate, the neck including channels therein for connecting the gas source to the channel in the plate.

8. A wand for transporting a wafer, the wand comprising:
a plate including a plurality of plate outlets for directing a gas flow against the wafer to hold the wafer using the Bernoulli principle, the plate having a neck to facilitate positioning the plate;
a plurality of locators extending from the plate and each including a locating outlet for directing a gas flow to locate the wafer laterally relative to the plate;
wherein the plate outlets and locating outlets operate to prevent the wafer from contacting the plate or the locator.

9. The wand of claim 8, wherein the plate defines a plane, and the locating outlet directs gas at an angle of between 0 degrees and 30 degrees with respect to the plane.

10. The wand of claim 9, wherein the angle at which at least one plate outlet directs gas with respect to the plane is different than the angle at which at least one other plate outlet directs gas with respect to the plane.

11. The wand of claim 9, wherein the angle at which at least one plate outlet directs gas with respect to the plane is selected to bias the wafer towards at least one of the plurality of locators.

12. The wand of claim 8, wherein the plate outlets are circular in shape.

13. The wand of claim 8, wherein one of the plurality of locators is configured to engage a notch disposed on an edge of the wafer.

14. The wand of claim 8, wherein each of the plurality of locators are spaced from each other.

15. The wand of claim 14, wherein the plate is circular and the locators are evenly spaced from each other along the circumference of the plate.

16. The wand of claim 8, wherein the plate and the plurality of locators are made of quartz.

17. The wand of claim 8, wherein the plate includes a channel disposed therein connecting a gas source to the plate outlets.

18. The wand of claim 17, wherein the plurality of locators each include a channel disposed therein connecting the gas source to the locating outlets.

19. The wand of claim 17, wherein the plurality of locators each include a conduit disposed externally from the locator connecting the gas source to the locating outlets.
